(19) United States
(12) Patent Application Publication
(10) Pub. No.: US 2013/0078788 A1
(43) Pub. Date: Mar. 28, 2013

(54) PRODUCING METHOD OF SEMICONDUCTOR DEVICE AND PRODUCTION DEVICE USED THEREFOR

(71) Applicant: Kyoichi SUGURO, Yokohama-shi (JP)

(72) Inventor: Kyoichi SUGURO, Yokohama-shi (JP)

(21) Appl. No.: 13/421,425

(22) Filed: Mar. 15, 2012

(30) Foreign Application Priority Data
Sep. 26, 2011 (JP) 2011-209629

(51) Int. Cl. H01L 21/265; C23C 16/511; C23C 16/50

(52) U.S. Cl. 438/513; 118/723 R; 118/723 MW; 257/E21.334

(57) ABSTRACT

According to one embodiment, a producing method for a semiconductor device comprises: heating a semiconductor substrate to thereby maintain a substrate temperature of the semiconductor substrate at a desired temperature and simultaneously dope the semiconductor substrate with conductive impurities; and performing an activation treatment for activating the conductive impurities for doping.

### CROSS-REFERENCE TO RELATED APPLICATION

This application is based upon and claims the benefit of priority from prior Japanese Patent Application No. 2011-209629 filed on Sep. 26, 2011, the entire contents of which are incorporated herein by reference.

### FIELD

The embodiments of the present invention relate to a producing method of a semiconductor device and a production device used therefor.

### BACKGROUND

Further micronization has been demanded for a semiconductor device, and particularly a minute transistor element with a gate length of 20 nm or less has been demanded in a peripheral circuitry of a nonvolatile semiconductor memory device. In accordance with the micronization of such a semiconductor device, in the case of forming an impurity diffusion layer by doping a narrow region such as a semiconductor substrate with conductive impurities, it has become more difficult to form without causing new problems.

### BRIEF DESCRIPTION OF THE DRAWINGS

FIG. 1 is a plan view for describing a producing method for a semiconductor device according to a first embodiment;

FIGS. 2A to 2D are cross-sectional views for describing a producing method for a semiconductor device according to the first embodiment;

FIGS. 3A to 3C are cross-sectional views for describing a producing method for a semiconductor device according to a second embodiment;

FIG. 4 is a cross-sectional view for describing a producing method for a semiconductor device according to a third embodiment;

FIGS. 5A to 5C are cross-sectional views for describing a producing method for a semiconductor device according to a fourth embodiment;

FIGS. 6A to 6G are cross-sectional views for describing a producing method for a semiconductor device according to a fifth embodiment;

FIGS. 7A to 7F are cross-sectional views for describing a producing method for a semiconductor device according to a sixth embodiment;

FIG. 8 is a cross-sectional view for describing a modification example of a producing method for a semiconductor device according to the sixth embodiment;

FIGS. 9A to 9D are cross-sectional views for describing a producing method for a semiconductor device according to a seventh embodiment;

FIG. 10 is a cross-sectional view for describing a producing method for a semiconductor device according to an eighth embodiment;

FIGS. 11A to 11C are cross-sectional views for describing a producing method for a semiconductor device according to a ninth embodiment;

FIG. 12 is a cross-sectional view for describing a producing method for a semiconductor device according to a tenth embodiment;

FIG. 13 is a cross-sectional view for describing a production device according to an eleventh embodiment;

FIG. 14 is a cross-sectional view for describing a production device according to a twelfth embodiment;

FIG. 15 is a view showing a correlation between substrate temperature and crystal defect density in the substrate in doping with conductive impurities; and

FIG. 16 is a view showing a correlation between substrate temperature and distribution of conductive impurities in the substrate in doping with conductive impurities.

### DETAILED DESCRIPTION

In one embodiment, a producing method for a semiconductor device comprises: heating a semiconductor substrate to thereby maintain a substrate temperature of the above-mentioned semiconductor substrate at a desired temperature and simultaneously dope the above-mentioned semiconductor substrate with conductive impurities; and performing an activation treatment for activating the above-mentioned conductive impurities for doping.

Embodiments are hereinafter described with reference to the drawings. Common reference numerals are put on common portions over all of the drawings and redundant descriptions are not repeated. The drawings are schematic views for promoting the description and understanding of the present invention; the shape, size and ratio thereof differ partially from the actual device, and may be properly modified in design in consideration of the following description and publicly known art. However, the present invention is not limited to these embodiments.

### First Embodiment

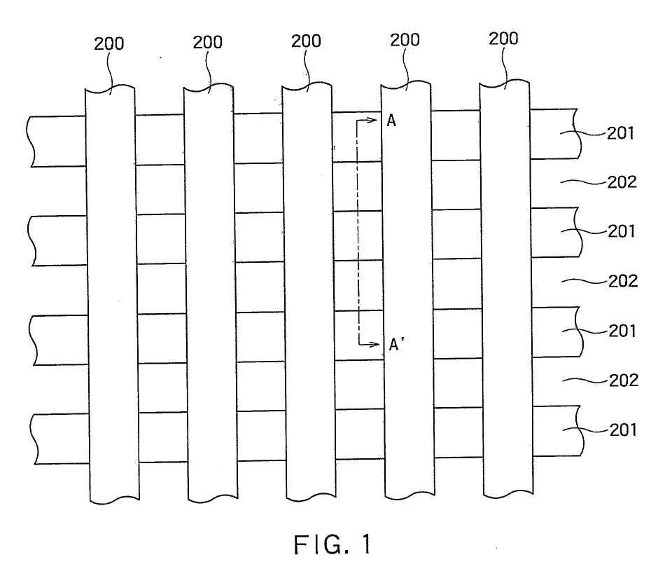

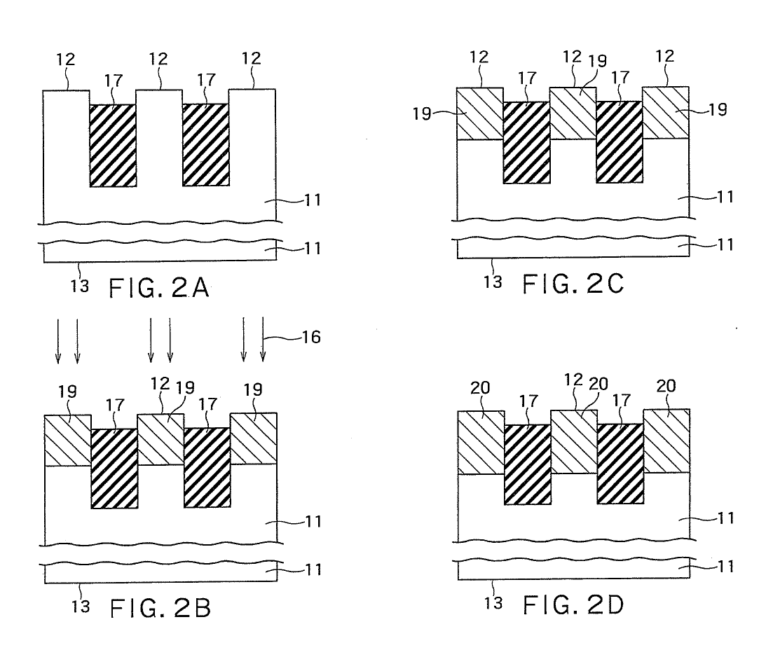

A producing method for a semiconductor device according to the present embodiment is described by using FIG. 1 and FIGS. 2A to 2D.

FIG. 1 is a plan view of a semiconductor device according to the present embodiment, for details, a plan view in a memory cell region of a semiconductor device in the present embodiment. First, as shown in FIG. 1, the semiconductor device in the present embodiment is a semiconductor memory device, and plural gate lines 200 are formed in a memory cell region thereof along the upward and downward direction of the page. In addition, these plural gate lines are disposed at regular intervals in the lateral direction of the page and parallel to each other. Plural active regions 201 are formed so as to be planarly orthogonal to the plural gate lines 200. These active regions 201 are disposed at regular intervals in the upward and downward direction of the page, and an STI (Shallow Trench Isolation) region 202 is formed therebetween. A trench is formed in this STI region 202, and an element isolation insulating film 17 described later is embedded in the trench. Plural memory cells are formed in plural portions in which each of the gate lines 200 and the active regions 201 intersect three-dimensionally.

A producing method for a semiconductor device according to the present embodiment is described by using FIGS. 2A to 2D. FIGS. 2A to 2D are principal cross-sectional views showing production steps for a semiconductor device according to the first embodiment; for details, FIGS. 2A to 2D correspond to cross-sectional views along the A-A′ line in FIG. 1.

First, a semiconductor layer (semiconductor substrate) 11 is prepared. This semiconductor layer 11 is made of silicon and may have p-type or n-type electrical conductivity in accordance with the conductive type of a transistor to be further formed.

Then, a tunnel insulating film (not shown in figures) and a part of a first polysilicon film (charge-storage film/floating gate) (not shown in figures) containing n-type or p-type impurities at a concentration of 1E20 cm⁻³ or more and 5E20 cm⁻³ or less are sequentially laminated on this semiconductor layer 11 to form a trench, which pierces through a part of the first polysilicon film and the tunnel insulating film into the semiconductor layer 11, by using an RIE (Reactive Ion Etching) method. For details, the tunnel insulating film is made of silicon oxide, a nitride oxide film, a hafnium-based oxide film (such as HfO₂) or a hafnium silicon oxynitride film (such as HfSiON). In the case of being silicon oxide, the tunnel insulating film may be formed by a thermal oxidation method. The first polysilicon film may be formed by a CVD method with the use of silane or disilane.

Next, the element isolation insulating film 17 is formed so as to be embedded in the trench previously formed by using an application method (such as Spin On Glass: SOG method) and a CVD (Chemical Vapor Deposition) method. This element isolation insulating film 17 may be formed by using a silicon oxide film. Thereafter, etching and CMP (Chemical Mechanical Polishing) are performed for the top surface of the element isolation insulating film 17 so that the top surface of the element isolation insulating film 17 is on a desired level.

In addition, the rest of the first polysilicon film (charge-storage film/floating gate) (not shown in figures), an IPD (Inter-Poly Dielectric) (inter-electrode insulating film) film (not shown in figures), and a second polysilicon film (control gate electrode) (not shown in figures) containing n-type or p-type impurities at a concentration of 1E20 cm⁻³ or more and 5E20 cm⁻³ or less are sequentially laminated to process these films by using RIE so as to form a gate structure with a desired shape, which is composed of these films. Thus, as shown in FIG. 2A, a structure such that the top surface of the semiconductor layer 11 is exposed between the element isolation insulating films 17 is obtained. The level of the top surface of the element isolation insulating film 17 is not limited to a level lower than the top surface of the semiconductor layer 11 as shown in FIG. 2A, and may be determined in accordance with the property of an intended semiconductor memory device. The second polysilicon film may be formed by a CVD method with the use of silane or disilane. In addition, the IPD film is composed of a multiple laminated film of a silicon oxide film and a silicon nitride film. The silicon oxide film of this IPD film may be formed by a thermal oxidation method, and the silicon nitride film thereof may be formed by a CVD method and an ALD (Atomic Layer Deposition) method.

Then, as shown in FIG. 2B, an impurity injection layer 19 is formed in the neighborhood of the top surface 12 of the semiconductor layer 11 by injecting n-type conductive impurities 16 such as As, P, and Sb when the semiconductor layer 11 is of p type; or injecting p-type conductive impurities 16 such as B, B and C or F lower in concentration than B, and BF₂, or p-type impurities and impurities 16 for slowing down diffusion of the p-type impurities into Si when the semiconductor layer 11 is of n-type. For details, after forming a mask pattern (a mask pattern which is capable of selectively etching Si, a silicon oxide film and a silicon nitride film, and is formed out of a material with heat resistance of 200° C. or more, such as a thin film made of C, TiN and Ge) for selectively injecting n-type or p-type impurities, the top surface 12 side of the semiconductor layer 11 is heated by using a tungsten halogen lamp, or an arc lamp of xenon or argon so that the substrate temperature of the semiconductor layer 11 is 200 to 500° C., preferably 300° C. (heating treatment). Alternatively, a back surface 13 side of the semiconductor layer 11 may be heated by using an electrostatic chuck with a hot plate. Also, the top surface 12 side and the back surface 13 side of the semiconductor layer 11 may be heated. In addition, the above-mentioned conductive impurities 16 are injected into the neighborhood of the top surface 12 of the semiconductor layer 11 on the conditions that acceleration energy is 1 keV to 60 keV and injection amount is 5E14 to 5E15 cm⁻² while maintaining the above-mentioned substrate temperature by continuing to heat after reaching desired temperature. The concentration of the conductive impurities 16 in the formed impurity injection layer 19 is in a range of 1E20 to 1E21 cm⁻³.

Thus, a crystal defect caused by the conductive impurities 16 injected into the semiconductor layer 11 may be immediately restored by performing ion implantation while heating. That is to say, the injected conductive impurities 16 have a certain energy even immediately after ion implantation, and the addition of energy obtained by heating to the energy allows a crystal defect to be sufficiently restored even in the case where heating temperature is low. Accordingly, as shown in FIG. 2C, the impurity injection layer 19 in which the defect does not exist continuously is formed. The details of the substrate temperature during ion implantation in the present embodiment are described later.

Next, as shown in FIG. 2D, the semiconductor layer 11 is subject to heat treatment (heating treatment) by heating for 10 minutes or less with the use of a tungsten halogen lamp, a xenon or argon arc lamp, an electromagnetic wave, or a hot plate so that the substrate temperature of the semiconductor layer 11 is 900° C. to 1000° C. to activate the conductive impurities 16 in the impurity injection layer 19 and then form an impurity diffusion layer 20. On this occasion, the heat treatment may be performed in an inert gas atmosphere or an atmosphere containing oxygen at a ratio of 10% or less.

The substrate temperature of the semiconductor layer 11 in ion implantation is measured by using a pyrometer through a glass fiber from the back surface 13 side of the semiconductor layer 11. For details, the temperature in the central portion or a region within 30 mm from the center of the back surface 13 of the semiconductor layer 11 is measured. Also, in the case where exact temperature measurement is necessary for process control, the measurement is performed in plural regions, such as the central portion, the outer periphery and the intermediate portion thereof of the back surface 13 of the semiconductor layer 11.

Thereafter, a desired semiconductor device is obtained through well-known steps.

According to the first embodiment, ion implantation while heating allows a crystal defect caused by ion implantation to be restored, so that a crystal defect may be greatly decreased.

For details, in a producing method of a semiconductor device ever studied by the inventors of the present invention, the conductive impurities 16 are injected into the semiconductor layer 11 by using an ion implantation method without heating, and the conductive impurities 16 are injected for such a short time that the injected conductive impurities 16 form interstitial atom and atomic vacancy continuously in the impurity injection layer 19 to amorphize a part or all of the impurity injection layer 19. The impurity injection layer 19 composed of an atom having a minute pattern once amorphized has a high-density crystal defect, which is completely restored with difficulty even in the case of thereafter performing RTA (Rapid Thermal Annealing) and the like at a high temperature of 900 to 1000° C.; accordingly, there is a high possibility that a high-density stacking fault remains in the impurity diffusion layer 20. Thus, in a region in which the high-density stacking fault exists, most of the injected conductive impurities 16 are electrically activated with difficulty, and the problem is occasionally caused that even though electrically activated once, the electrically activated conductive impurities 16 are caught by the crystal defect in the step performed thereafter and electrically deactivated. In addition, leak current resulting from a crystal defect such as a dislocation defect occasionally occurs in a formed semiconductor device.

The injected conductive impurities 16 occasionally enter atomic vacancy and a gap between atoms composing a crystal in the impurity injection layer 19 to expand the volume of the impurity injection layer 19, which is amorphized. Also, in such a case, this high-density crystal defect is completely restored with difficulty by RTA thereafter; accordingly, a high-density stacking fault remains in the impurity diffusion layer 20 and the high-density activated conductive impurities 16 are obtained with difficulty.

However, in the present embodiment, ion implantation while heating allows a crystal defect caused by the implantation to be restored, so that a crystal defect (a crystal defect density) may be greatly decreased. Accordingly, the high-concentration activated conductive impurities 16 may be obtained and the occurrence of leak current resulting from a crystal defect such as a dislocation defect may be avoided. By extension, the yield may be improved in the production of a semiconductor device.

### Second Embodiment

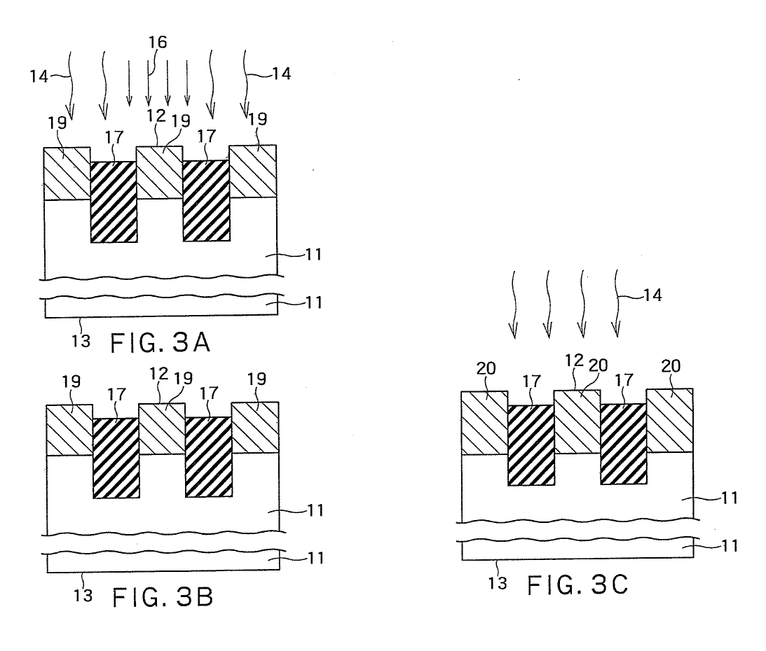

The second embodiment differs from the first embodiment in performing not heating treatment but microwave treatment (microwave irradiation) during ion implantation. A producing method for a semiconductor device according to the present embodiment is described by using FIGS. 3A to 3C. These FIGS. 3A to 3C are principal cross-sectional views showing production steps for a semiconductor device according to the second embodiment. In the following description of the present embodiment, the same reference numerals as the first embodiment are put on portions having the same constitution and function as the first embodiment, and the descriptions thereof are not repeated here.

First, the steps up to FIG. 2A in the first embodiment are performed.

Next, as shown in FIG. 3A, similarly to the first embodiment, an impurity injection layer 19 is formed by injecting conductive impurities 16 such as As, P, B, and BF₂ in the neighborhood of a top surface 12 of a semiconductor layer 11 on the conditions that acceleration energy is 1 keV to 60 keV and injection amount is 5E14 to 5E15 cm⁻² by using an ion implantation method. On that occasion, a microwave 14 of 2.45 GHz or more, desirably, 5.80 GHz to 30 GHz is irradiated on the top surface 12 side of the semiconductor layer 11. Thus, the substrate temperature of the semiconductor layer 11 is maintained at 200 to 500° C. while irradiating the microwave 14. A frequency band centering on 5.80 GHz is assigned to ISM (Industry-Science-Medical) band ((Industry-Science-Medical Band)), so that the performance is comparatively easy. Also, the power density of the microwave to be used is desirably determined so as to be 50 W to 1500 W per 1 cm², and the pressure in a chamber preferably approximates to 1 atm for preventing anomalous discharge in the chamber.

Thus, the injection of the conductive impurities 16 while irradiating the microwave 14 allows ion implantation to be performed while restoring a crystal defect caused by ion implantation. Thus, as shown in FIG. 3B, the impurity injection layer 19 in which the defect does not exist continuously is formed.

Then, the microwave 14 of 2.45 GHz or more, desirably, 5.80 GHz to 30 GHz is irradiated on the semiconductor layer 11 from the top surface 12 side of the semiconductor layer 11 to activate the injected conductive impurities 16 and then form an impurity diffusion layer 20 as shown in FIG. 3C. On this occasion, the power density of the microwave 14 is desirably determined so as to be 50 W to 1500 W per 1 cm², and the irradiation time is desirably within three minutes. Subsequently, a desired semiconductor device is obtained through well-known steps.

According to the second embodiment, the injection of the conductive impurities 16 while irradiating the microwave 14 allows a crystal defect caused by injecting the conductive impurities 16 to be efficiently restored by the effect of microwave irradiation, and allows the impurity injection layer 19 with few crystal defects to be formed. Also, the microwave 14 is long in wavelength as compared with infrared rays and high in permeability into the crystal, so that the microwave 14 may efficiently reach a necessary spot; accordingly, in the case where a semiconductor device has a metal layer and a metal oxide layer subject to thermal damage, these layers may avoid being damaged and desired device performance may be obtained. By extension, the yield may be improved in the production of a semiconductor device.

In addition, the microwave is irradiated not merely in the case of injecting the conductive impurities 16 but also the microwave is irradiated in the case of activating the injected conductive impurities 16 to form the impurity diffusion layer 20, so that the conductive impurities 16 may be activated more efficiently. Also, in the case where a semiconductor device has a metal layer and a metal oxide layer subject to thermal damage, these layers may further avoid being damaged; therefore, desired device performance may be obtained, and by extension, the yield may be further improved in the production of a semiconductor device.

That is to say, the present embodiment utilizes the property of the microwave 14. The property of the microwave 14 is described below.

The microwave 14 generally signifies an electromagnetic wave with a wavelength of 300 MHz to 300 GHz; accordingly, in the microwave 14, an electric field and a magnetic field exist so as to be vertical to each other in the traveling direction of the wave. Then, these electric field and magnetic field become the maximum at the spot where the wave offers the maximum amplitude and zero at the moment when the amplitude of the wave becomes zero.

Here, the description is offered on the assumption that the semiconductor layer 11 is made of a silicon crystal; when impurities and crystal defects (atomic vacancy, interstitial atom and unbound atom) exist in this silicon crystal, electric charge (electron) distribution occurs in the silicon crystal. In particular, in the case of impurities, the impurity atom and the silicon atom differ in electronegativity so much that an electron is leaning to an atom easily attracting an electron (negatively charged) while the other atom is in a state of being short of an electron (positively charged). Thus, an electric dipole is formed in the silicon crystal. Then, when the microwave 14 is irradiated on such a silicon crystal, this electric dipole vibrates in accordance with the electric field of the microwave 14.

In addition, the property of the microwave 14 is described while comparing with infrared rays used in heat treatment such as RTA (Rapid Thermal Annealing) and furnace annealing.

With regard to infrared rays, the wavelength thereof is as short as 10 μm and is as high a frequency as 30 THz in terms of frequency, so that the irradiation of infrared rays on the silicon crystal causes stretching vibration of bond between the adjacent silicon atoms in the silicon crystal and causes torsional vibration (rotation vibration) of bond between the silicon atoms with difficulty. Such stretching vibration does not cause the position of the silicon atoms to move largely, so that rearrangement of bond between the silicon atoms is caused with difficulty.

On the other hand, in the case of irradiating the microwave 14 on the silicon crystal, the bond of four sp³ hybrid orbitals between the silicon atoms vibrates so as to be distorted, so that rearrangement of bond between the silicon atoms is caused so efficiently that the crystal defect may be restored. Also, the microwave 14 is long in wavelength as compared with infrared rays and high in permeability into the silicon crystal. Accordingly, the microwave 14 reaches a necessary spot efficiently.

However, even though the microwave 14 is irradiated, 2.45 GHz as a frequency of a household microwave oven is so low in frequency that it is difficult to efficiently cause torsional vibration of bond between the silicon atoms. On the other hand, when the frequency exceeds 30 GHz, torsional vibration of bond between the silicon atoms begins to be incapable of following. Accordingly, when the frequency is determined at the intermediate range between these frequencies, such as 5.80 GHz, torsional vibration of bond between the silicon atoms is efficiently caused and rearrangement of the silicon atoms is easily caused efficiently.

Thus, microwave treatment is treatment different from heat treatment in that torsional vibration of bond between the silicon atoms may be efficiently caused, and a change in the position of the atoms, that is, rearrangement of bond is caused so easily that the crystal defect may be efficiently restored.

In the present embodiment, before injecting the conductive impurities 16 while irradiating the microwave 14, impurities such as F (electronegativity is 4.0), C (electronegativity is 2.5) and N (electronegativity is 3.0), different by 1 or more in electronegativity from atoms (such as Si and Ge with an electronegativity of 1.8) mainly composing the semiconductor layer 11 are preferably injected by a smaller amount than the injection amount of the conductive impurities 16. Hereinafter, the description is offered on the assumption that the semiconductor layer 11 is made of a silicon crystal; the injection of impurities, such as F, C and N, different by 1 or more in electronegativity from the silicon atom composing the semiconductor layer 11 causes local deviation in electron distribution in the impurity injection layer 19, so that rotation vibration or torsional vibration of a diamond lattice of silicon is efficiently caused by microwave irradiation and the crystal defect caused by ion implantation may be restored more effectively, and by extension, the impurity diffusion layer 20 with few crystal defects may be formed. On this occasion, the impurity injection layer 19 is preferably doped by using ion implantation or plasma doping so that the concentration of impurities such as F, C and N is a third or less with respect to the concentration of the conductive impurities such as As, P and B (a range of 1E20 to 1E21 cm⁻³).

Also in the present embodiment, similarly to the first embodiment, heating may be performed by using a tungsten halogen lamp in doping with the conductive impurities by ion implantation, and the impurity diffusion layer 20 may be formed by activating the conductive impurities in the impurity doping layer 15 while the microwave 14 is irradiated.

### Third Embodiment

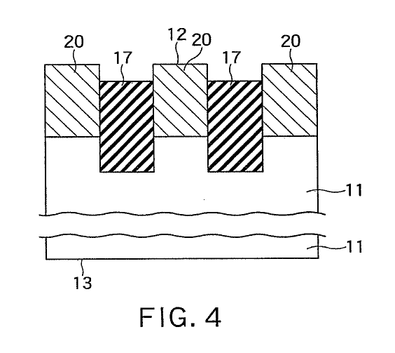

The third embodiment differs from the second embodiment in replacing microwave irradiation with heating treatment during the formation of the impurity diffusion layer 20 by activating the injected conductive impurities 16. A producing method for a semiconductor device according to the present embodiment is described by using FIG. 4. This FIG. 4 is a principal cross-sectional view showing production steps for a semiconductor device according to the third embodiment. In the following description of the present embodiment, the same reference numerals as the first and second embodiments are put on portions having the same constitution and function as the first and second embodiments, and the descriptions thereof are not repeated here.

First, similarly to the second embodiment, the steps up to FIG. 2A in the first embodiment are performed and the steps shown in FIGS. 3A and 3B in the second embodiment are performed.

Next, similarly to the first embodiment, as shown in FIG. 4, the semiconductor layer 11 is subject to heat treatment (heating treatment) by heating for 3 minutes or less with the use of a tungsten halogen lamp so that the substrate temperature of the semiconductor layer 11 is 900° C. to 1000° C. to activate the conductive impurities 16 in the impurity injection layer 19 and then form an impurity diffusion layer 20. On this occasion, the heat treatment may be performed in an inert gas atmosphere or an atmosphere containing oxygen at a ratio of 10% or less. Subsequently, a desired semiconductor device is obtained through well-known steps.

According to the third embodiment, even though heating treatment is used during the formation of the impurity diffusion layer 20 by activating the injected conductive impurities 16, similarly to the second embodiment, the doping with the conductive impurities while irradiating the microwave 14 allows a crystal defect caused by doping with the conductive impurities to be efficiently restored by the effect of microwave irradiation, and allows an impurity dope layer 15 with few crystal defects to be formed.

### Fourth Embodiment

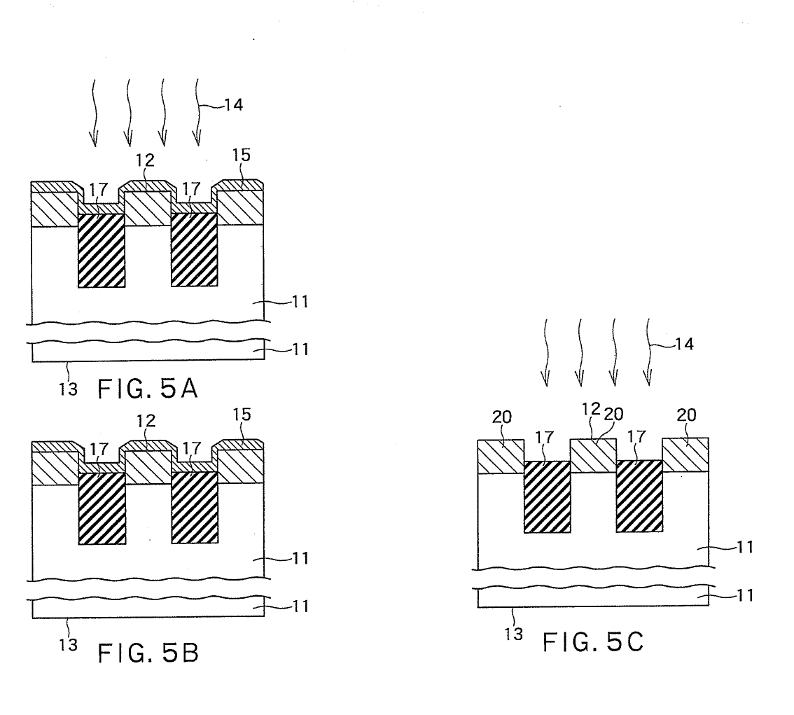

The fourth embodiment differs from the second embodiment in doping the semiconductor layer 11 with conductive impurities such as As, P, Sb and B by replacing ion implantation of the conductive impurities with plasma doping. A producing method for a semiconductor device according to the present embodiment is described by using FIGS. 5A to 5C. FIGS. 5A to 5C are principal cross-sectional views showing production steps for a semiconductor device according to the fourth embodiment. In the following description of the present embodiment, the same reference numerals as the first to third embodiments are put on portions having the same constitution and function as the first to third embodiments, and the descriptions thereof are not repeated here.

First, the steps up to FIG. 2A in the first embodiment are performed.

Next, as shown in FIG. 5A, the doping with the conductive impurities (not shown in figures) is performed by a plasma doping method. For details, in the case of attempting to dope with the conductive impurities at an injection amount of 1E15 to 1E16 cm⁻², plasma doping is performed by using hydrogenated gas or fluorinated gas containing the conductive impurities such as As, P, Sb, B and Ge under the conditions that acceleration energy is 150 eV to 10 key. On this occasion, similarly to the second embodiment, the microwave 14 of 2.45 GHz or more, desirably, 5.8 GHz to 30 GHz is irradiated on the top surface 12 side of the semiconductor layer 11. Thus, as shown in FIG. 5B, an impurity doping layer 15 in which the defect does not exist continuously is formed.

Also, thus, the doping with the conductive impurities by using a plasma doping method allows the doping with the conductive impurities to be performed at high concentration and wide range for a short time, and the energy of the individual conductive impurities in doping is so low that the production of a crystal defect in doping may be further decreased.

Then, similarly to the second embodiment, the microwave 14 of 2.45 GHz or more, desirably, 5.8 GHz to 30 GHz is irradiated to activate the conductive impurities in the impurity doping layer 15 and then form an impurity diffusion layer 20 as shown in FIG. 5C. Subsequently, a desired semiconductor device is obtained through well-known steps.

According to the fourth embodiment, similarly to the second embodiment, the doping with the conductive impurities while irradiating the microwave 14 allows a crystal defect caused by doping with the conductive impurities to be efficiently restored by the effect of microwave irradiation, and allows the impurity dope layer 15 with few crystal defects to be formed. Also, according to the present embodiment, the doping with the conductive impurities by using a plasma doping method allows the doping with the impurities to be performed at high concentration and wide range for a short time, and the energy of the individual conductive impurities in doping is so low that the production of a crystal defect in doping may be further decreased. By extension, the yield may be improved in the production of a semiconductor device.

The microwave is irradiated not merely in the case of doping with the conductive impurities but also the microwave is irradiated in the case of activating the doped conductive impurities to form the impurity diffusion layer 20, so that the conductive impurities may be activated more efficiently. Also, in the case where a semiconductor device has a metal layer and a metal oxide layer subject to thermal damage, these layers may further avoid being damaged; therefore, desired device performance may be obtained, and by extension, the yield may be further improved in the production of a semiconductor device.

Also in the present embodiment, similarly to the second embodiment, before doping with the conductive impurities while irradiating the microwave 14, impurities such as F, C and N, different by 1 or more in electronegativity from silicon atoms mainly composing the semiconductor layer 11 may be injected, and the injection of impurities such as F, C and N allows the crystal defect to be restored more effectively by the microwave irradiation.

Also in the present embodiment, similarly to the first embodiment, heating may be performed by using a tungsten halogen lamp in doping with the conductive impurities by a plasma doping method, and the impurity diffusion layer 20 may be formed by activating the conductive impurities in the impurity doping layer 15 while heating. Moreover, in the present embodiment, heating may be performed by using a tungsten halogen lamp in doping with the conductive impurities by a plasma doping method, and the impurity diffusion layer 20 may be formed by activating the conductive impurities in the impurity doping layer 15 while the microwave 14 is irradiated.

### Fifth Embodiment

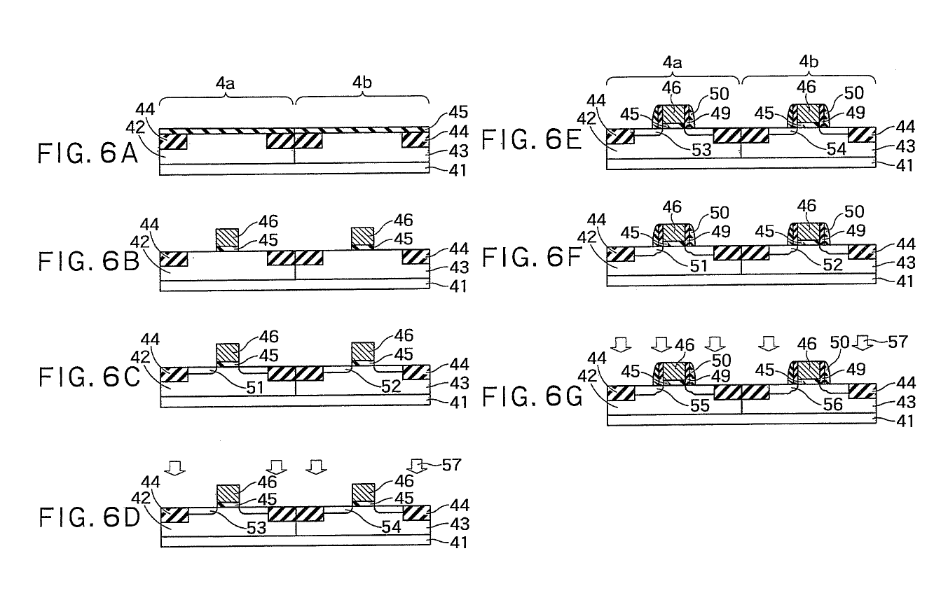

In the present embodiment, a producing method for a CMOS (Complementary Metal Oxide Semiconductor) transistor as a semiconductor device is described by using FIGS. 6A to 6G. FIGS. 6A to 6G are principal cross-sectional views showing production steps for a semiconductor device according to the fifth embodiment; the case of forming an n-type transistor in an nMOS region 4a and a p-type transistor in a pMOS region 4b shown in these figures is described as an example, and the present invention is not limited thereto but may be applied to a producing method for other transistors. In the following description of the present embodiment, the detailed descriptions of the same points as the embodiments described above are not repeated here.

First, as shown in FIG. 6A, a p-type well 42 and an n-type well 43 as a semiconductor layer and an element isolation insulating film 44 are formed on a p-type substrate 41 having as the main component silicon previously doped with B (boron) of approximately 2E15 cm⁻³ to thereafter form a gate insulating film 45.

For details, the p-type well 42 is formed in the nMOS region 4a and the n-type well 43 is formed in the pMOS region 4b. The element isolation insulating film 44 is formed in a boundary between the p-type well 42 and the n-type well 43 by a CVD method, for example. The element isolation insulating film 44 may be formed by using a silicon oxide film, for example. The gate insulating film 45 is formed with a film thickness of 5 nm or less on the p-type well 42 and the n-type well 43. The gate insulating film 45 may be formed by using SiOxNy or metal oxide or metal silicate of Hf, Zr, La, Al and Ti.

Next, as shown in FIG. 6B, a gate electrode 46 is formed by a CVD method. This gate electrode 46 may adopt a conductive film of any of a polycrystalline silicon film or metal silicide, metal nitride and metal carbide injected with p-type or n-type conductive impurities at a concentration of 1E20 cm⁻³ or more, or a laminate of a polycrystalline silicon film or a metal film on the conductive film. In the steps thereafter, in the case where conductive impurities to be injected into an impurity injection layer is not injected into the gate electrode 46 for forming a source drain region, a metal nitride film or a laminate of a metal nitride film and a silicon film may be formed directly on the gate electrode 46.

Then, as shown in FIG. 6C, conductive impurities such as As, P and B are injected into the nMOS region 4a and the pMOS region 4b by an ion implantation method to form shallow impurity injection layers 47 and 48. On this occasion, the conductive impurities are injected while heating similarly to the first embodiment described above.

For details, the pMOS region 4b is masked so that the pMOS region 4b is not injected with n-type conductive impurities. On this occasion, it is desirable to mask with a carbon film or a silicon nitride film with a thickness of 50 nm or less, which is more heat-resistant than a photoresist. Then, conductive impurities such as P are injected into the nMOS region 4a at an injection amount of 1E14 cm⁻² to 2E15 cm⁻² by an ion implantation method to form the impurity injection layer 47. On this occasion, heating is performed by using a tungsten halogen lamp so that the substrate temperature of the p-type substrate 41 is 200 to 500° C. Subsequently, after removing the mask, the nMOS region 4a is next masked similarly and conductive impurities such as B are injected into the pMOS region 4b at an injection amount of 1E14 cm⁻² to 2E15 cm⁻² by an ion implantation method to form the shallow impurity injection layer 48. Also on this occasion, heating is performed so that the substrate temperature of the p-type substrate 41 is 200 to 500° C. similarly to the formation of the above-mentioned shallow impurity injection layer 47. In the case of forming the impurity injection layers 47 and 48 with a depth of 20 nm or less, the injection of the above-mentioned conductive impurities is preferably performed by using a plasma doping method instead of ion implantation.

Next, as shown in FIG. 6D, similarly to the second embodiment, a microwave 57 of 2.45 GHz or more, desirably, 5.8 GHz to 30 GHz is irradiated to activate the injected conductive impurities and then form shallow impurity diffusion layers 53 and 54.

In addition, as shown in FIG. 6E, a silicon oxide film 49 and a silicon nitride film 50 are formed on the side face of the gate electrode 46. For details, the silicon oxide film is formed on the nMOS region 4a and the pMOS region 4b by a CVD method to expose the top surface of the element isolation insulating film 44 and part of the top surface of the shallow impurity diffusion layers 53 and 54 by an RIE method. Subsequently, the silicon nitride film is formed on the nMOS region 4a and the pMOS region 4b by a CVD method to expose the top surface of the element isolation insulating film 44 and part of the top surface of the shallow impurity diffusion layers 53 and 54 by an RIE method, whereby a sidewall having a laminated structure of the silicon oxide film 49 and the silicon nitride film 50 is formed on the side face of the gate electrode 46.

Then, as shown in FIG. 6F, conductive impurities such as As, P and B are injected into the nMOS region 4a and the pMOS region 4b by an ion implantation method to form deep impurity injection layers 51 and 52. On this occasion, the conductive impurities are injected while heating similarly to the formation of the shallow impurity injection layers 47 and 48 described above.

For details, after the pMOS region 4b is masked, conductive impurities such as P are injected into the nMOS region 4a at an injection amount of 2E15 cm⁻² to 5E15 cm⁻² by an ion implantation method to form the deep impurity injection layer 51 expanding more deeply than the shallow impurity diffusion layer 53 from the top surface of the p-type well 42. On this occasion, similarly to the first embodiment, heating is performed by using a tungsten halogen lamp so that the substrate temperature of the p-type substrate 41 is 200 to 500° C. Subsequently, after removing the mask, the nMOS region 4a is masked and conductive impurities such as B are injected into the pMOS region 4b by an ion implantation method to form the deep impurity injection layer 52 expanding more deeply than the shallow impurity diffusion layer 54 from the top surface of the n-type well 43. Also on this occasion, heating is performed similarly to the formation of the above-mentioned deep impurity injection layer 51. In the case of forming the deep impurity injection layers 51 and 52 with a depth of 20 nm or less, the injection of the above-mentioned conductive impurities is preferably performed by using a plasma doping method. Similarly to the above, it is desirable to use as a mask a carbon film or a silicon nitride film with a thickness of 100 nm or less, which is more heat-resistant than a photoresist.

Next, as shown in FIG. 6G, similarly to the second embodiment, the microwave 57 of 2.45 GHz or more, desirably, 5.8 GHz to 30 GHz is irradiated to activate the injected conductive impurities and then form deep impurity diffusion layers 55 and 56.

In the above-mentioned description, the irradiation of the microwave 57 for activating the conductive impurities is performed twice, and yet the first microwave irradiation may be omitted in the case where the injection amount of the conductive impurities is small.

Subsequently, a desired transistor is obtained through well-known steps.

According to the fifth embodiment, ion implantation while heating allows a crystal defect caused by ion implantation to be restored, so that a crystal defect may be greatly decreased. By extension, the yield may be improved in the production of a semiconductor device.

### Sixth Embodiment

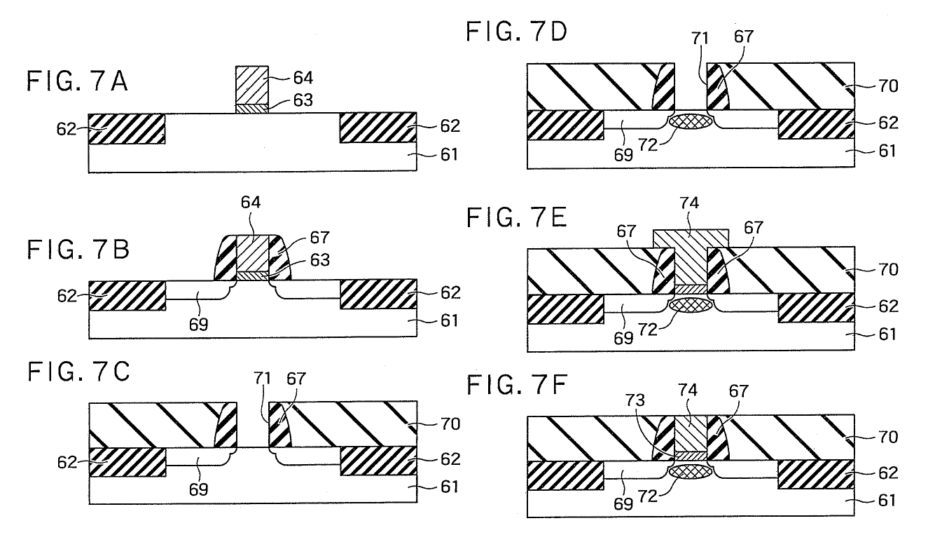

In the present embodiment, an example of a producing method for a CMOS transistor different from the fifth embodiment is described, and a producing method for forming one of nMOS and pMOS in a CMOS transistor is herein described as an example. FIGS. 7A to 7F are principal cross-sectional views showing production steps for a semiconductor device according to the sixth embodiment. In the following description of the present embodiment, the same reference numerals as the embodiments described above are put on portions having the same constitution and function as the embodiments described above, and the detailed descriptions thereof are not repeated here.

First, as shown in FIG. 7A, an element isolation insulating film 62 are formed on a substrate 61 as a semiconductor layer by a CVD method to subsequently form a dummy insulating film 63 and a dummy gate 64 on the substrate 61. For details, this substrate 61 is a substrate having silicon as the main component. The dummy insulating film 63 is made of SiO₂ or SiOxNy, and the dummy gate 64 is made of silicon or carbon. For further details, a material film for the dummy insulating film 63 is formed on the substrate 61 by a thermal oxidation method. Subsequently, a material film for the dummy gate 64 is formed on the dummy insulating film 63 by a CVD method to form the dummy insulating film 63 and the dummy gate 64 with a desired shape by a photolithographic method and an RIE method.

Next, conductive impurities such as As, P and B in accordance with electrical conductivity of a CMOS transistor are injected at an injection amount of 1E14 cm⁻² to 2E15 cm⁻² by an ion implantation method while using the dummy gate 64 as a mask to form a shallow impurity injection layer (not shown in figures) with a depth of 20 nm or less from the top surface of the substrate 61. On this occasion, similarly to the first embodiment, heating is performed by using a tungsten halogen lamp so that the substrate temperature of the substrate 61 is 200 to 500° C. A plasma doping method may be used instead of ion implantation.

Then, a sidewall 67 is formed on the side face of the dummy gate 64. This sidewall 67 is made of an insulating film, and may be made of a silicon oxide film, a silicon nitride film, or a laminated structure of a silicon oxide film and a silicon nitride film. The silicon nitride film is preferably composed so that a nitrogen atom is 1 or more and 3.5 or less with respect to one silicon atom. For details, the insulating film is formed on the whole surface of the substrate 61 by a CVD method to subsequently form the sidewall 67 by removing the insulating film so as to expose part of the substrate 61 and the element isolation insulating film 62 by an RIE method.

In addition, conductive impurities such as As, P and B in accordance with electrical conductivity of a CMOS transistor are injected into a region as a source drain region in the substrate 61 at an injection amount of 2E15 cm⁻² to 5E15 cm⁻² by an ion implantation method to form a deep impurity injection layer (not shown in figures) ranging more deeply than a shallow impurity diffusion layer from the top surface of the substrate 61. On this occasion, similarly to the first embodiment, heating is performed by using a tungsten halogen lamp so that the substrate temperature of the substrate 61 is 200 to 500° C.

Next, similarly to the second embodiment, the microwave of 2.45 GHz or more, desirably, 5.8 GHz to 30 GHz is irradiated to activate the injected conductive impurities and then form a deep impurity diffusion layer 69 as shown in FIG. 7B.

Then, an interlayer insulating film 70 is formed on the substrate 61 by a CVD method to expose the dummy gate 64 by flattening the interlayer insulating film 70 by a CMP (Chemical Mechanical Polishing) method. This interlayer insulating film 70 may be formed out of a silicon oxide film or a fluoridated silicon oxide film (SiOF) with lower dielectric constant than a silicon oxide film. In addition, as shown in FIG. 7C, the dummy insulating film 63 under the dummy gate 64 is removed together with the exposed dummy gate 64 by using dry etching and wet etching in combination such as an RIE method to form an opening 71 in the interlayer insulating film 70.

In addition, as shown in FIG. 7D, conductive impurities are injected into a portion of the exposed substrate 61 through the opening 71 by an ion implantation method while using the interlayer insulating film 70 as a mask to form a local channel 72. For details, conductive impurities of a conductive type opposite to the impurities injected into the deep impurity diffusion layer 69, such as impurities of Sb and As, are injected into a channel region at an injection amount of 1E11 cm⁻² to 3E13 cm⁻² to form the local channel region 72 for preventing a short circuit of the source drain composed of the deep impurity diffusion layer 69.

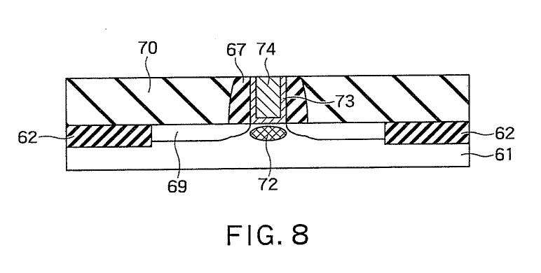

Next, as shown in FIG. 7E, a gate insulating film 73 is formed with a film thickness of 5 nm or less at the bottom of the opening 71 by a CVD method. The gate insulating film 73 may be formed out of a silicon oxynitride film (SiOxNy) or metal oxide or metal silicate of Hf, Zr, La, Al and Ti. Here, the case where a thermal oxide film is formed at the bottom of the opening 71 to form the gate insulating film 73 by further nitriding the thermal oxide film with plasma is shown in FIGS. 7E and 7F. Also, the gate insulating film 73 may be formed on the whole surface of the opening 71 (the sidewall and the bottom of the opening 71) by a CVD method. Also, here, the dummy gate 64 and the dummy insulating film 63 are removed in FIG. 7C and the gate insulating film 73 is formed anew in the step shown in FIG. 7E, but yet only the dummy gate 64 may be removed in FIG. 7C to leave the dummy insulating film 63 as the gate insulating film 73. Subsequently, a conductive film of any of metal silicide, metal nitride and metal carbide is formed as a gate electrode 74 on the gate insulating film 73 so as to embed the opening 71. Alternatively, a metal film with lower resistivity is laminated on the above-mentioned conductive film to form the gate electrode 74. For details, the gate electrode 74 is formed in such a manner that the conductive film composing the gate electrode 74 is accumulated on the gate insulating film 73 to process the gate electrode 74 by reactive ion etching, and this conductive film is accumulated to thereafter remove the conductive film except the trench or hole portion by CMP or CMP and gas cluster ion beam. Thus, the gate electrode 74 as shown in FIG. 7F may be obtained. Subsequently, a desired transistor is obtained through well-known steps. In the case where the gate insulating film 73 is formed on the whole surface of the opening 71 by a CVD method, a transistor of a modification example as shown in FIG. 8 may be obtained.

According to the sixth embodiment, ion implantation while heating allows a crystal defect caused by ion implantation to be restored, so that a crystal defect may be greatly decreased. By extension, the yield may be improved in the production of a semiconductor device.

### Seventh Embodiment

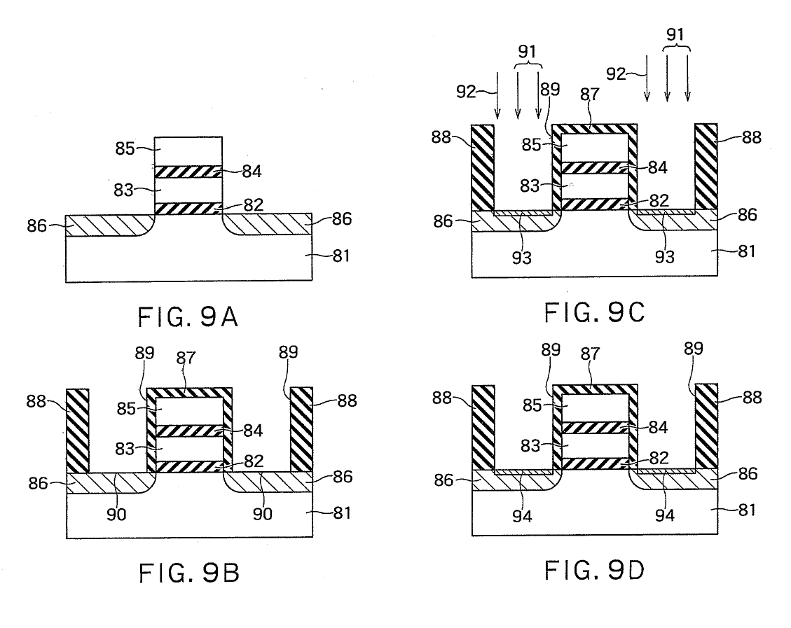

A producing method for a semiconductor device according to the present embodiment is described by using FIGS. 9A to 9D. FIGS. 9A to 9D are principal cross-sectional views showing production steps for a semiconductor device according to the seventh embodiment. Here, the case of forming an impurity diffusion layer 94 at a bottom 90 of a contact hole 89 is described, and the present invention is not limited to a producing method for such a semiconductor memory device but may be applied to the formation of a source drain region and the formation of a transistor having another structure. In the following description of the present embodiment, the same reference numerals as the embodiments described above are put on portions having the same constitution and function as the embodiments described above, and the detailed descriptions thereof are not repeated here.

A semiconductor layer 81 as shown in FIG. 9A is made of silicon. A tunnel insulating film 82, a first polysilicon film (floating gate) 83, an IPD film 84, and a second polysilicon film (control gate) 85 are sequentially formed on this semiconductor layer 81. Then, these films are processed by using RIE so as to form a gate structure of a desired shape, which is composed of these films. In addition, a source drain region 86 is formed in the neighborhood of the top surface of the semiconductor layer 81 so as to hold the above-mentioned gate structure therebetween. This source drain region 86 may be formed by injecting conductive impurities through ion implantation while performing heating treatment or irradiating a microwave, similarly to the first embodiment or the second embodiment.

Next, as shown in FIG. 9B, a sidewall 87 composed of an insulating film covering the above-mentioned gate structure and an interlayer insulating film 88 located on the semiconductor layer 81 are formed. This interlayer insulating film 88 may be formed by using a silicon oxide film. In addition, the plural contact holes 89 are formed in the interlayer insulating film 88 by using an RIE method, and part of the source drain region 86 is exposed at the bottom 90 of these contact holes 89.

Then, as shown in FIG. 9C, first and second impurities 91 and 92 are injected by an ion implantation method into the source drain region 86 of the semiconductor layer 81 exposed to the contact holes 89 to form an impurity injection layer 93.

For details, first, the second impurities 92 for restraining the first impurities 91 from diffusing are injected. Examples of these second impurities 92 include impurities containing C, F or N as the form of an atomic ion or a molecular ion. For further details, examples of the second impurities 92 include carbon in the form of an atomic ion, and carbon containing at least one kind of the form of a molecular ion which satisfies C_{d}Hₑ (d is an integer of 2 or more and e is an integer of 6 or more) such as C₇H₇, C₁₂H₁₂ or C₁₄H₁₄. In addition, examples of the second impurities 92 include a molecular ion containing fluorine such as F₂ and PF₃, and a molecular ion containing nitrogen such as N₂ and NH₃. The second impurities 92 are preferable such that contact resistivity and leak current in a semiconductor device rise with difficulty even in the case of increasing impurity concentration of the second impurities 92; accordingly, impurities containing carbon are the most preferable and impurities containing fluorine are secondly preferable. However, when fluorine concentration increases greatly, there is a possibility that leak current of a semiconductor device rises, so that it is not preferable to use impurities containing fluorine as the second impurities 92 in a semiconductor device in which the conditions regarding leak current are strict.

For example, in a diluent gas atmosphere of helium or hydrogen, the second impurities 92 are injected into the source drain region 86 exposed to the bottom 90 of the contact holes 89. These second impurities 92 are preferably injected by a smaller amount than the first impurities 91, more preferably by an amount of 20% or less of the first impurities 91. On this occasion, the substrate temperature is preferably determined lower than the substrate temperature during the injection of the first impurities 91 performed thereafter, more preferably determined at room temperature or lower. Such injection of the second impurities 92 allows a damage layer (a crystal defect layer) to be formed in the impurity injection layer 93, and the presence of the damage layer allows an orbit of the first impurities 91 in the impurity injection layer 93 to be thereafter disordered and disturbed during the injection of the first impurities 91, that is, channeling to be restrained, and allows the first impurities 91 to be restrained from diffusing. Accordingly, the first impurities 91 may be distributed more steeply.

Subsequently, the first impurities 91 are injected. P and B in the form of a molecular ion except for the atomic conductive impurities such as P, B and As described above may be used as the first impurities (conductive impurities) 91 for controlling the conductive type of the impurity injection layer 93. For details, examples of P in the form of a molecular ion include P containing at least one kind of molecular ions which satisfy Pa (a is an integer of 2 or more) such as P₂ or P₄, and examples of B in the form of a molecular ion include B containing at least one kind of molecular ions which satisfy B_{b}H_{c} (b is an integer of 2 or more and c is an integer of 6 or more) such as B₁₀H₁₄, B₁₈H₂₂, B₂₀H₂₈ or B₃₆H₄₄.

These first impurities 91 are injected into the source drain region 86 on the conditions of an injection amount of 1E15 cm⁻² to 5E15 cm⁻². On this occasion, similarly to the first embodiment, the semiconductor layer 81 is heated by using a tungsten halogen lamp so that the substrate temperature of the semiconductor layer 81 is 200 to 500° C. Thus, similarly to the embodiments described above, a crystal defect caused by the first and second impurities 91 and 92 may be restored.

The order of the injection of the first impurities 91 and the second impurities 92 is not limited to the above, and the injection of these impurities is more preferably in an order of injecting the second impurities 92 before injecting the first impurities 91. The performance of the injection in this order may restrain diffusion during the injection of the first impurities 91 as compared with the case of injecting simultaneously or in inverse order, and the first impurities 91 may be distributed more steeply.

Next, as shown in FIG. 9D, similarly to the first embodiment, the semiconductor layer 81 is heated from the top surface side of the semiconductor layer 81 by using a tungsten halogen lamp so that the substrate temperature of the semiconductor layer 81 is 900 to 1000° C. to activate the first impurities 91 in the impurity injection layer 93 and then form the impurity diffusion layer 94.

Subsequently, a desired transistor is obtained through well-known steps.

According to the seventh embodiment, ion implantation while heating allows a crystal defect caused by ion implantation to be restored, so that a crystal defect may be greatly decreased. By extension, the yield may be improved in the production of a semiconductor device. In addition, the injection of the second impurities 92 allows channeling of the first impurities 91 to be restrained, diffusion of the first impurities 91 to be restrained, the first impurities 91 to be distributed more steeply, and the thinner impurity diffusion layer 94 to be formed.

### Eighth Embodiment

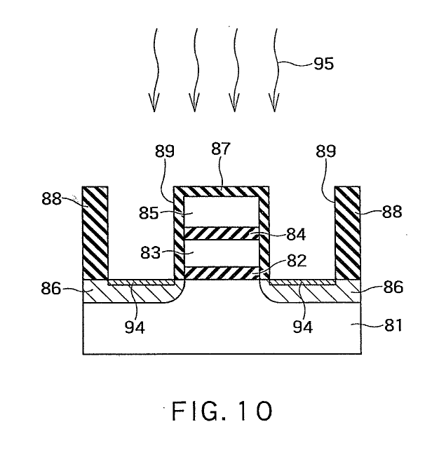

The eighth embodiment differs from the seventh embodiment in irradiating a microwave 95 instead of heating treatment in activating the first impurities 91 in the impurity injection layer 93 to form the impurity diffusion layer 94. A producing method for a semiconductor device according to the present embodiment is described by using FIG. 10. This FIG. 10 is a principal cross-sectional view showing production steps for a semiconductor device according to the eighth embodiment. In the following description of the present embodiment, the same reference numerals as the seventh embodiment are put on portions having the same constitution and function as the seventh embodiment, and the descriptions thereof are not repeated here.

First, the steps shown in FIGS. 9A to 9C in the seventh embodiment are performed.

Next, similarly to the second embodiment, the microwave 95 of 2.45 GHz or more, desirably, 5.8 GHz to 30 GHz is irradiated to activate the first impurities 91 in the impurity injection layer 93 and then form the impurity diffusion layer 94 as shown in FIG. 10. Subsequently, a desired semiconductor device is obtained through well-known steps.

According to the eighth embodiment, ion implantation while heating allows a crystal defect caused by ion implantation to be restored, so that a crystal defect may be greatly decreased. By extension, the yield may be improved in the production of a semiconductor device. In addition, the injection of the second impurities 92 allows channeling of the first impurities 91 to be restrained, diffusion of the first impurities 91 to be restrained, the first impurities 91 to be distributed more steeply, and the thinner impurity diffusion layer 94 to be formed.

### Ninth Embodiment

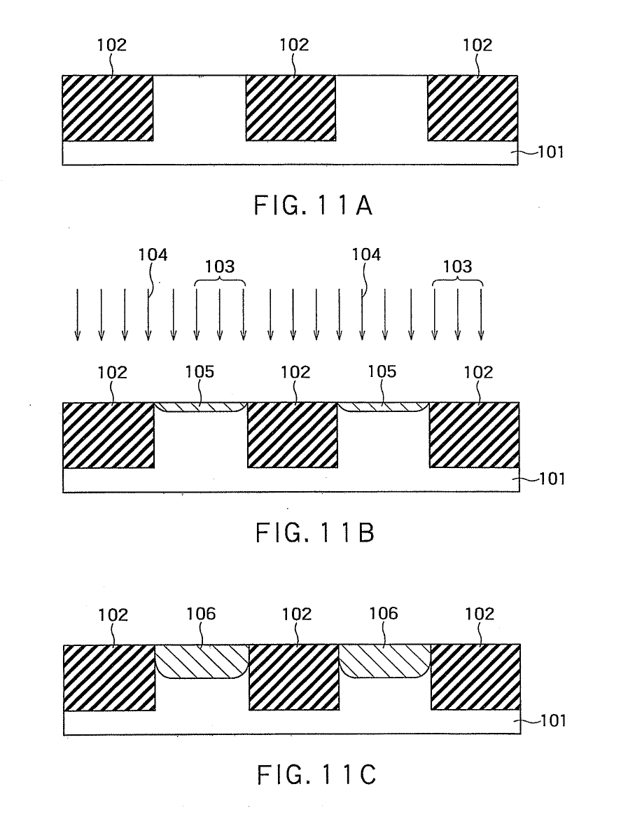

The ninth embodiment is a producing method for a semiconductor device such as to inject conductive impurities into a narrow region surrounded by an element isolation insulating film 102, and this narrow region is a region 40 nm or less square. The present embodiment is described by using FIGS. 11A to 11C. FIGS. 11A to 11C are principal cross-sectional views showing production steps for a semiconductor device according to the ninth embodiment. In the following description of the present embodiment, the same reference numerals as the embodiments described above are put on portions having the same constitution and function as the embodiments described above, and the detailed descriptions thereof are not repeated here.

As shown in FIG. 11A, the element isolation insulating film 102 is formed in a semiconductor layer 101 made of silicon by using a well-known method. This element isolation insulating film 102 may be formed by using a silicon oxide film. An interval between the element isolation insulating films 102 is 40 nm.

Next, as shown in FIG. 11B, similarly to the seventh and eighth embodiments, first and second impurities 103 and 104 are injected by an ion implantation method into the semiconductor layer 101 located between the element isolation insulating films 102 to form an impurity injection layer 105.

For details, carbon, fluorine or nitrogen as the second impurities 104 for restraining the first impurities 103 from diffusing is injected into the semiconductor layer 101 located between the element isolation insulating films 102, similarly to the seventh and eighth embodiments. The injection amount is 1E14 cm⁻² to 1E15 cm⁻². On this occasion, similarly to the seventh and eighth embodiments, the substrate temperature is preferably determined lower than the substrate temperature during the injection of the first impurities 103 performed thereafter, more preferably determined at room temperature or lower. Next, conductive impurities such as As, P and B are injected as the first impurities 103 by an ion implantation method on the conditions of an injection amount of 5E14 cm⁻² to 5E15 cm⁻² while heating from the top surface side of the semiconductor layer 101 by using a tungsten halogen lamp so that the substrate temperature is 200 to 500° C. Alternatively, a back surface side of the semiconductor layer 101 may be heated by using an electrostatic chuck with a hot plate. Also, the top surface side and the back surface side of the semiconductor layer 101 may be heated. Thus, the impurity injection layer 105 is formed in the semiconductor layer 101 located between the element isolation insulating films 102. Thus, the performance of heating simultaneously with ion implantation allows ion implantation to be performed while restoring a crystal defect.

Next, as shown in FIG. 11C, the semiconductor layer 101 is heated by using a tungsten halogen lamp so that the substrate temperature of the semiconductor layer 101 is 900 to 1000° C. to activate the injected first impurities 103 and then form an impurity diffusion layer 106. Subsequently, a desired semiconductor device is obtained through well-known steps.

According to the ninth embodiment, ion implantation while heating allows a crystal defect caused by ion implantation to be restored, so that a crystal defect may be greatly decreased. By extension, the yield may be improved in the production of a semiconductor device. In addition, the injection of the second impurities 104 allows channeling of the first impurities 103 to be restrained, diffusion of the first impurities 103 to be restrained, and the thinner impurity diffusion layer 106 to be formed.

### Tenth Embodiment

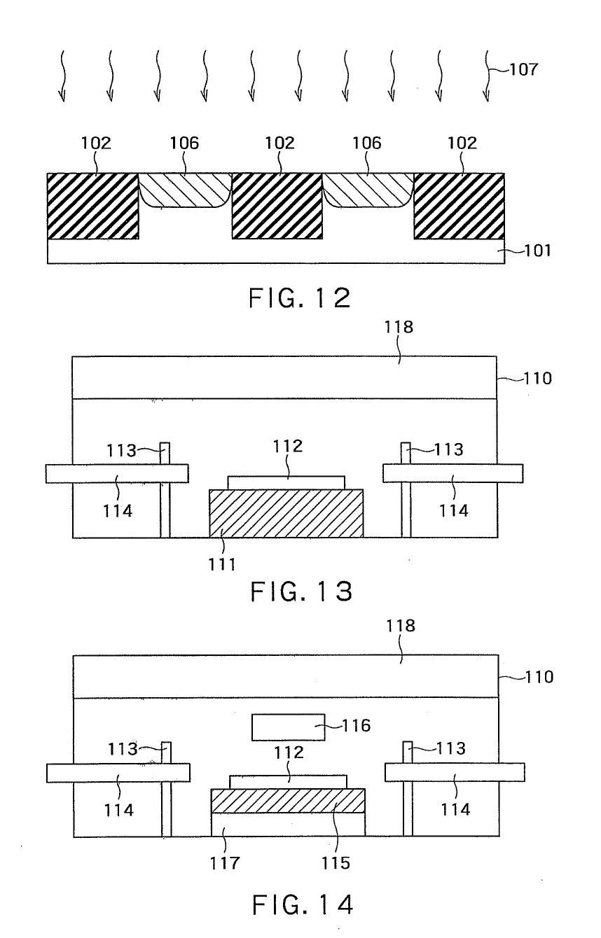

The tenth embodiment differs from the ninth embodiment in irradiating a microwave 107 instead of heating treatment in activating the first impurities 103 in the impurity injection layer 105 to form the impurity diffusion layer 106. A producing method for a semiconductor device according to the present embodiment is described by using FIG. 12. This FIG. 12 is a principal cross-sectional view showing production steps for a semiconductor device according to the tenth embodiment. In the following description of the present embodiment, the same reference numerals as the ninth embodiment are put on portions having the same constitution and function as the ninth embodiment, and the descriptions thereof are not repeated here.

First, the steps shown in FIGS. 11A and 11B in the ninth embodiment are performed.

Next, similarly to the second embodiment, the microwave 107 of 2.45 GHz or more, desirably, 5.8 GHz to 30 GHz is irradiated to activate the first impurities 103 in the impurity injection layer 105 and then form the impurity diffusion layer 106 as shown in FIG. 12. Subsequently, a desired semiconductor device is obtained through well-known steps.

According to the tenth embodiment, ion implantation while heating allows a crystal defect caused by ion implantation to be restored, so that a crystal defect may be greatly decreased. By extension, the yield may be improved in the production of a semiconductor device. In addition, the injection of the second impurities 104 allows channeling of the first impurities 103 to be restrained, diffusion of the first impurities 103 to be restrained, and the thinner impurity diffusion layer 106 to be formed.

### Eleventh Embodiment

The eleventh embodiment is a production device usable in a producing method for a semiconductor device of the embodiments described above, whereby doping of conductive impurities may be performed by a plasma doping method while heating. FIG. 13 shows an example of a production device of the present embodiment. The present invention is not limited to the following embodiment but may be also applied to a production device having another structure.

As shown in FIG. 13, a metal chamber 110 capable of generating electron-dense plasma has a discharge unit 118 for generating plasma in the upper part thereof, and a susceptor (a substrate stage) 111 with an alternating substrate bias application function (a bias mechanism) in the lower part thereof. This susceptor 111 has a hot plate (a heating apparatus) capable of heating a substrate (a semiconductor substrate) 112 up to 200 to 500° C. The substrate 112 is placed on this susceptor 111. In addition, the susceptor 111 is surrounded by a shield cover made of quartz 113. Then, the chamber 110 has a gas introduction unit 114 for introducing gas containing conductive impurities for doping into the substrate 112, which unit may introduce impurity-containing gases such as B₂H₆, BF₃, PH₃, PF₃, AsH₃, AsF₃, SbF₃, InI, GeH₄, GeF₄, CH₄, CF₄ and C₂H₆ into the chamber 110; accordingly, the substrate 112 may be doped with conductive impurities such as B, P, As, Sb, In, Ge, C and F while heated. Accordingly, the use of such a device allows doping of conductive impurities to be performed while heated, and allows a crystal defect caused by conductive impurities to be restored, so that a crystal defect may be greatly decreased.

### Twelfth Embodiment

The twelfth embodiment is a device usable for performing a producing method for a semiconductor device of the embodiments described above, and differs from the production device of the eleventh embodiment in that doping of conductive impurities may be performed by a plasma doping method while irradiating a microwave. FIG. 14 shows an example of a production device of the present embodiment. In the following description of the present embodiment, the same reference numerals as the eleventh embodiment are put on portions having the same constitution and function as the eleventh embodiment, and the descriptions thereof are not repeated here.

Here, only the difference from the device of the eleventh embodiment is described, and as shown in FIG. 14, a metal chamber 110 capable of forming electron-dense plasma has a susceptor 115 with an alternating substrate bias application function instead of the susceptor 111 of the eleventh embodiment. A microwave inlet tube 116 for introducing a microwave of 2.45 GHz or more, desirably, 5.8 GHz to 30 GHz into the chamber is disposed by at least four pieces, at most approximately ten pieces on the periphery (chamber inner wall) of a substrate 112 disposed in the susceptor 115. In addition, this susceptor 115 is also provided with a movable mechanism 117 for moving the level of the top surface of the substrate 112 disposed in the susceptor 115 by ±3 cm or more in the upward and downward direction with respect to the position of the microwave inlet tube 116. Accordingly, the use of such a device allows doping of conductive impurities to be performed while irradiated with a microwave, and allows a crystal defect caused by conductive impurities to be restored, so that a crystal defect may be greatly decreased.

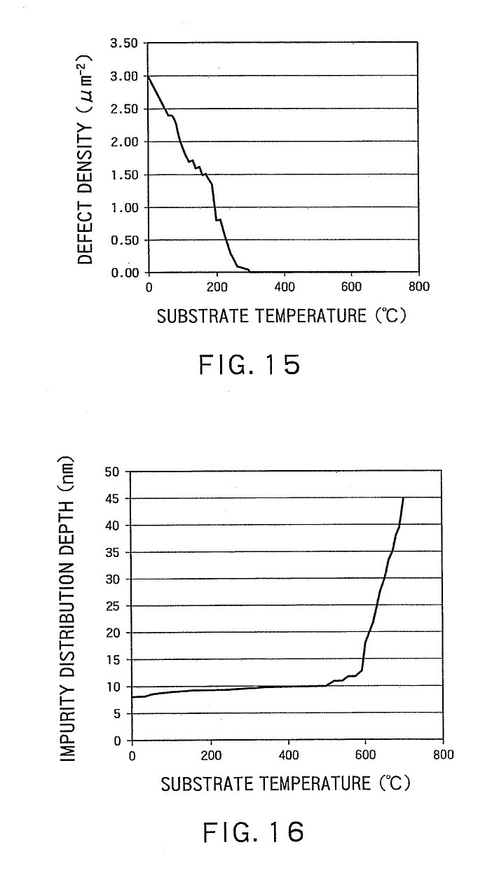

In the first to twelfth embodiments described above, the substrate temperature of the semiconductor layer in doping the semiconductor layer with the conductive impurities 16 is determined at 200 to 500° C., and this substrate temperature allows the effect of restoring a crystal defect to be expected and allows the conductive impurities 16 to avoid diffusing deep into the semiconductor layer more than necessary. The details of the substrate temperature of the semiconductor layer in doping the semiconductor layer with the conductive impurities 16 are described below by using FIGS. 15 and 16 showing the data of the experiment performed by the inventors of the present invention.

The inventors of the present invention ion-implanted P (phosphorus) as the conductive impurities 16 into a 20 nm-wide silicon layer held between silicon oxide films while heating similarly to the above-mentioned embodiments. On this occasion, plural samples were produced by modifying heating temperature (substrate temperature). Next, similarly to the above-mentioned embodiments, the plural samples were irradiated with a microwave to activate the conductive impurities 16 and then form an impurity diffusion layer in the silicon layer in the plural samples. In addition, when a crystal defect density of the impurity diffusion layer in these plural samples was measured, the data showing a correlation between the substrate temperature and the crystal defect density was offered as shown in FIG. 15. According to this data, it was confirmed that a crystal defect density decreased when the substrate temperature during the ion implantation was 200° C. or more.

Next, similarly to the above, the inventors of the present invention ion-implanted B (boron) as the conductive impurities 16 into a 20 nm-wide silicon layer held between silicon oxide films while heating similarly to the above-mentioned embodiments (the concentration was 5E18 cm⁻³). On this occasion, plural samples were produced by modifying heating temperature (substrate temperature). Next, similarly to the above-mentioned embodiments, the plural samples were irradiated with a microwave to activate the conductive impurities 16 and then form an impurity diffusion layer in the silicon layer in the plural samples. In addition, when the depth of the distribution of boron (the depth from the surface of the silicon layer) in these plural samples was measured, the data showing a correlation between the substrate temperature and the depth of the distribution of boron was offered as shown in FIG. 16. The reason for using boron as the conductive impurities 16 is to have the property of being subject to thermal diffusion more easily than phosphorus. According to this data, it was confirmed that the diffusion of boron became greatly remarkable at a temperature of more than 500° C. Therefore, it was found that the upper limit of the substrate temperature in doping with the conductive impurities 16 was desirably approximately 500° C. or less.

Based on the above data, it is desirable for expecting the effect of restoring a crystal defect and avoiding the deep diffusion of the conductive impurities 16 into the semiconductor layer more than necessary that the substrate temperature of the semiconductor layer in doping the semiconductor layer with the conductive impurities 16 is determined at 200 to 500° C.

The modification example described in the second embodiment, such that impurities such as F, C and N are injected before injecting the conductive impurities 16, may be also applied to the first, third, fifth and sixth embodiments; thus, channeling of the conductive impurities 16 is restrained and diffusion of the conductive impurities 16 is restrained, so that the conductive impurities 16 may be distributed more steeply.

The method for injecting the first impurities as the conductive impurities 16 and the second impurities for restraining channeling of the first impurities, described in the seventh embodiment, may be applied to the first to tenth embodiments, including the case where the second impurities are in the form of a molecular ion.

In injecting the impurities for restraining channeling of the conductive impurities 16, the substrate temperature is preferably determined lower than the substrate temperature during the injection of the conductive impurities 16, more preferably determined at room temperature or lower.

In the first to twelfth embodiments described above, the semiconductor substrate is not limited to a substrate made of silicon but may be other substrates such as a SiGe substrate, a Ge substrate and a C substrate. Also, the semiconductor substrate may be such various substrates on which a semiconductor element structure and an insulating layer are formed entirely or partially.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A producing method for a semiconductor device comprising:
heating a semiconductor substrate to thereby maintain a substrate temperature of the semiconductor substrate at a desired temperature and simultaneously dope the semiconductor substrate with conductive impurities; and
performing an activation treatment for activating the conductive impurities for doping.

2. The producing method for a semiconductor device according to claim 1, wherein the desired temperature is 200° C. to 500° C.

3. The producing method for a semiconductor device according to claim 1, wherein a doping of the conductive impurities is performed by an ion implantation method or a plasma doping.

4. The producing method for a semiconductor device according to claim 1, further comprising doping with impurities containing at least one of fluorine, carbon and nitrogen before doping with the conductive impurities.

5. The producing method for a semiconductor device according to claim 1, further comprising doping with molecular impurities containing at least one of fluorine, carbon and nitrogen before doping with the conductive impurities.

6. The producing method for a semiconductor device according to claim 1, wherein the activation treatment is a heat treatment.

7. The producing method for a semiconductor device according to claim 6, wherein the heat treatment is performed so that the substrate temperature of the semiconductor substrate becomes 900° C. to 1000° C.

8. The producing method for a semiconductor device according to claim 1, wherein the activation treatment is a microwave treatment.

9. The producing method for a semiconductor device according to claim 8, wherein a microwave used in the microwave treatment has a frequency of 2.45 GHz to 30 GHz.

10. A producing method for a semiconductor device comprising:
irradiating a semiconductor substrate with a microwave and simultaneously doping the semiconductor substrate with conductive impurities; and
performing an activation treatment for activating the conductive impurities for doping.

11. The producing method for a semiconductor device according to claim 10, wherein the microwave has a frequency of 2.45 GHz to 30 GHz.

12. The producing method for a semiconductor device according to claim 10, wherein a doping of the conductive impurities is performed by an ion implantation method or a plasma doping.

13. The producing method for a semiconductor device according to claim 10, further comprising doping with impurities containing at least one of fluorine, carbon and nitrogen before doping with the conductive impurities.

14. The producing method for a semiconductor device according to claim 10, wherein the activation treatment is a heat treatment.

15. The producing method for a semiconductor device according to claim 14, wherein the heat treatment is performed so that a substrate temperature of the semiconductor substrate becomes 900° C. to 1000° C.

16. The producing method for a semiconductor device according to claim 10, wherein the activation treatment is a microwave treatment.

17. The producing method for a semiconductor device according to claim 16, wherein a microwave used in the microwave treatment has a frequency of 2.45 GHz to 30 GHz.

18. A production device for a semiconductor device for doping a semiconductor substrate with conductive impurities by using a plasma doping method, comprising:
a chamber;
a substrate stage mounted with the semiconductor substrate;
an impurity gas introduction unit for introducing gas containing the conductive impurities into the chamber; and
a discharge unit for generating plasma;
wherein the substrate stage has a bias mechanism for applying bias on the semiconductor substrate.

19. The production device for a semiconductor device according to claim 18, wherein the substrate stage further has a heating apparatus for heating the semiconductor substrate.

20. The production device for a semiconductor device according to claim 18, further comprising a plurality of microwave inlet tubes for introducing a microwave into the chamber.
